(19) United States
(12) Patent Application Publication
(10) Pub. No.: US 2024/0423075 A1
(43) Pub. Date: Dec. 19, 2024

(54) DISPLAY APPARATUS

(71) Applicant: Samsung Display Co., LTD., Yongin-si (KR)

(72) Inventors: Gijung LEE, Yongin-si (KR); Yongchul KIM, Yongin-si (KR); Hongyoub NA, Yongin-si (KR); Juyeon SEO, Yongin-si (KR); Dongyoon SO, Yongin-si (KR); Heechul JEON, Yongin-si (KR)

(21) Appl. No.: 18/740,701

(22) Filed: Jun. 12, 2024

(30) Foreign Application Priority Data
Jun. 15, 2023 (KR) 10-2023-0077012

(51) Int. Cl. H10K 59/80; H10K 59/122

(52) U.S. Cl. CPC H10K 59/8792; H10K 59/122; H10K 59/873

(57) ABSTRACT

A display apparatus includes: a substrate; a display element disposed on the substrate; a pixel-defining layer disposed on the substrate and defining an opening that defines an emission area of the display element; a spacer disposed on the pixel-defining layer and defining a first opening that overlaps the opening of the pixel-defining layer; a thin-film encapsulation layer disposed on the display element; and a light-shielding layer disposed on the thin-film encapsulation layer and defining a second opening corresponding to the emission area of the display element, where a size of the first opening is greater than or equal to a size of the second opening in a plan view.

This application claims priority to Korean Patent Application No. 10-2023-0077012, filed on Jun. 15, 2023, and all the benefits accruing therefrom under 35 U.S.C. § 119, the content of which in its entirety is herein incorporated by reference.

### BACKGROUND

### 1. Field

One or more embodiments relate to display apparatuses.

### 2. Description of the Related Art

A display apparatuses has been used for various purposes. As the display apparatus has become thinner and more lightweight, the range of use thereof has widened, and as the display apparatus has been used in various fields, demands for the display apparatus for providing high-quality images have increased.

### SUMMARY

One or more embodiments include a display apparatus on which high-quality images may be provided by reducing reflection of external light. However, the one or more embodiments are only examples, and the scope of the disclosure is not limited thereto.

Additional aspects will be set forth in part in the description that follows and, in part, will be apparent from the description, or may be learned by practice of the embodiments of the disclosure.

According to one or more embodiments, a display apparatus includes: a substrate, a display element disposed on the substrate; a pixel-defining layer disposed on the substrate and defining an opening that defines an emission area of the display element; a spacer disposed on the pixel-defining layer and defining a first opening that overlaps the opening of the pixel-defining layer; a thin-film encapsulation layer disposed on the display element; and a light-shielding layer disposed on the thin-film encapsulation layer and defining a second opening corresponding to the emission area of the display element, where a size of the first opening is greater than or equal to a size of the second opening in a plan view.

The spacer may include a first portion having a certain shape, and a second portion that defines the first opening.

The first portion and the second portion may be integrally provided as a single body.

A thickness of the first portion may be greater than a thickness of the second portion.

A thickness of the first portion may be about 8,000 angstroms (Å) to about 15,000 Å, and a thickness of the second portion may be about 2,000 Å to about 6,000 Å.

The size of the second opening may be greater than a size of the opening of the pixel-defining layer in the plan view.

The pixel-defining layer may include a light-blocking material.

The spacer may include photosensitive polyimide (“PSPI”).

The display apparatus may further include a color filter in the second opening of the light-shielding layer.

The display apparatus may further include: a reflection control layer in the second opening of the light-shielding layer, wherein the reflection control layer absorbs a first wavelength range of about 480 nanometers (nm) to about 505 nm, and a second wavelength range of about 585 nm to about 605 nm.

The display apparatus may further include a touch sensing layer between the thin-film encapsulation layer and the light-shielding layer.

According to one or more embodiments, a display apparatus includes: a substrate; a display element disposed on the substrate; a pixel-defining layer disposed on the substrate and defining an opening that defines an emission area of the display element; a spacer disposed on the pixel-defining layer and defining a first opening that overlaps the opening of the pixel-defining layer; a thin-film encapsulation layer disposed on the display element; and a light-shielding layer disposed on the thin-film encapsulation layer and defining a second opening corresponding to the emission area of the display element, wherein, in a plan view, an edge of the spacer that defines the first opening surrounds an edge of the light-shielding layer that defines the second opening.

The spacer may include a first portion having a certain shape, and a second portion extending from the first portion and defining the first opening.

A thickness of the first portion may be greater than a thickness of the second portion.

A size of the first opening may be greater than or equal to a size of the second opening.

A size of the second opening may be greater than a size of the opening of the pixel-defining layer.

The pixel-defining layer may include a light-blocking material.

The display apparatus may further include a color filter in the second opening of the light-shielding layer.

The display apparatus may further include a reflection control layer in the second opening of the light-shielding layer, wherein the reflection control layer absorbs a first wavelength range of about 480 nm to about 505 nm, and a second wavelength range of about 585 nm to about 605 nm.

The thin-film encapsulation layer may include, on the spacer, a first inorganic encapsulation layer, an organic encapsulation layer, and a second inorganic encapsulation layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to an embodiment;

FIG. 2 illustrates a display element provided in any one pixel of a display apparatus according to an embodiment, and a pixel circuit connected thereto;

FIGS. 3A and 3B are schematic cross-sectional views of a display apparatus according to an embodiment, taken along line I-I′ in FIG. 1;

FIG. 4 is an enlarged plan view of some components of an embodiment, which may be included in region A in FIG. 1;

FIG. 5 is a schematic cross-sectional view of a display apparatus according to an embodiment, and corresponds to a cross-section taken along line II-II′ in FIG. 4;

FIG. 6 is a schematic cross-sectional view of a display apparatus according to a Comparative Example, and illustrates an example of light reflection;

FIG. 7 is an enlarged plan view of some components of an embodiment, which may be included in region A in FIG. 1; and

FIG. 8 is a cross-sectional view schematically illustrating a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

In an embodiment below, terms such as “first” and “second” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, terms such as “include” or “comprise” may be construed to denote a certain characteristic or element, or a combination thereof, but may not be construed to exclude the existence of or a possibility of addition of one or more other characteristics, elements, or combinations thereof.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

It will be understood that when a layer, region, or component is referred to as being “connected” to another layer, region, or component, it may be “directly connected” to the other layer, region, or component or may be “indirectly connected” to the other layer, region, or component with other layer, region, or component therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component therebetween.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or 5% of the stated value.

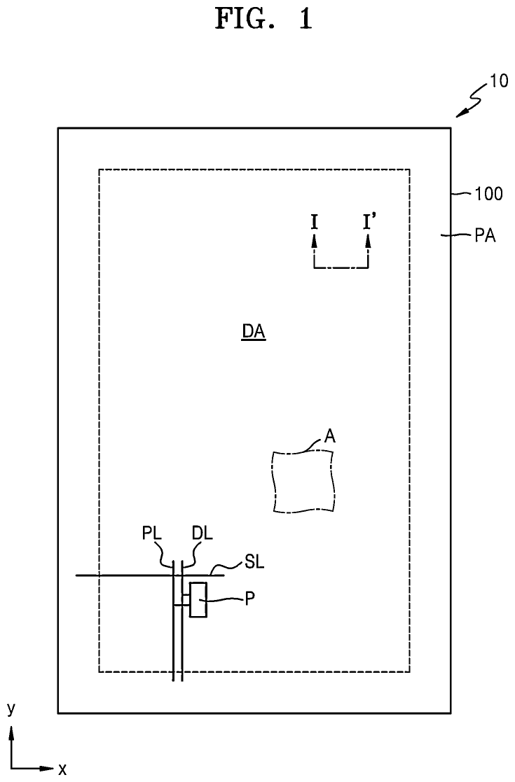

FIG. 1 is a plan view schematically illustrating a display apparatus 10 according to an embodiment. As used herein, the “plan view” is a view in a z direction (i.e., thickness direction of the substrate 100).

Referring to FIG. 1, a substrate 100 of the display apparatus 10 may be divided into a display area DA and a peripheral area PA around the display area DA. The display apparatus 10 may provide an image by using light emitted from a plurality of pixels P arranged in the display area DA.

Each of the pixels P may include a display element, such as an organic light-emitting diode or an inorganic light-emitting diode, and may emit, for example, red, green, blue, or white light. In other words, each of the pixels P may be connected to a pixel circuit including a thin-film transistor, a storage capacitor, etc. Such a pixel circuit may be connected to a scan line SL, and a data line DL and a driving voltage line PL, which cross the scan line SL. The scan line SL may be provided to extend in an x direction, and the data line DL and the driving voltage line PL may be provided to extend in a y direction.

By driving of the pixel circuit, each of the pixels P may emit light, and the display area DA may provide an image through light emitted from the pixels P. As described above, the pixel P as used herein may be defined as an emission area for emitting one of red, green, blue, and white light.

The pixel area PA is an area in which the pixels P are not arranged, and may not provide an image. In the peripheral area PA, a built-in drive circuit unit for driving the pixels P, a power supply line, and a terminal unit to which a printed circuit board, which includes the driving circuit unit, or a driver integrated circuit (“IC”) are connected may be arranged.

The display apparatus 10 according to an embodiment may include an organic light-emitting display, an inorganic light-emitting display, a quantum dot display, etc. Although it is described below that an organic light-emitting display is described as an example of a display apparatus according to an embodiment, the display apparatus of the disclosure is not limited thereto, and the features to be described below may be applied to various types of display apparatuses, as described above.

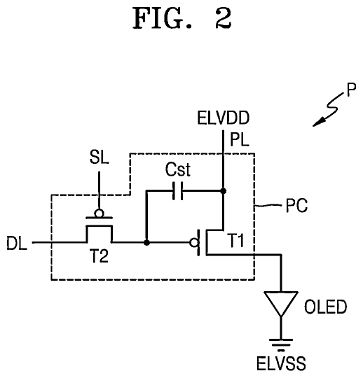

FIG. 2 illustrates a display element provided in one pixel P of a display apparatus according to an embodiment, and a pixel circuit connected thereto.

Referring to FIG. 2, an organic light-emitting diode OLED, which is a display element, may be connected to a pixel circuit PC. The pixel circuit PC may include a first thin-film transistor T1, a second thin-film transistor T2, and a storage capacitor Cst. In an embodiment, for example, the organic light-emitting diode OLED may emit one of red, green, and blue light, or one of red, green, blue, and white light.

The second thin-film transistor T2, which is a switching thin-film transistor, may be connected to the scan line SL and the data line DL and may transfer a data voltage received via the data line DL to the first thin-film transistor T1 according to a switching voltage received via the scan line SL. The storage capacitor Cst may be connected to the second thin-film transistor T2 and the driving voltage line PL and may store a voltage corresponding to a voltage difference between a voltage received from the second thin-film transistor T2 and a first power voltage ELVDD supplied to the driving voltage line PL.

The first thin-film transistor T1, which is a driving transistor, may be connected to the driving voltage line PL and the storage capacitor Cst, and may control a drive current flowing from the driving voltage line PL to the organic light-emitting diode OLED, in response to a voltage value stored in the storage capacitor Cst. The organic light-emitting diode OLED may emit light having a luminance according to the driving current. An opposite electrode (e.g., a cathode) of the organic light-emitting diode OLED may receive a second power voltage ELVSS.

In FIG. 2, the pixel circuit PC includes two thin-film transistors and one storage capacitor. However, in another embodiment, the number of thin-film transistors and the number of storage capacitors may be variously modified depending on the design of the pixel circuit PC.

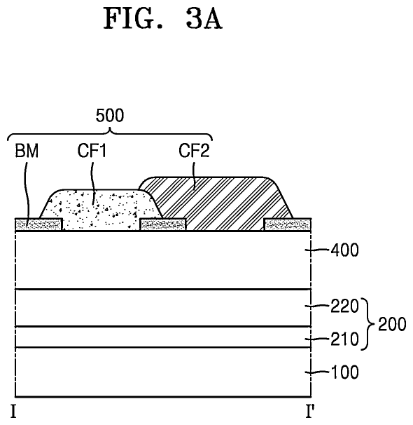

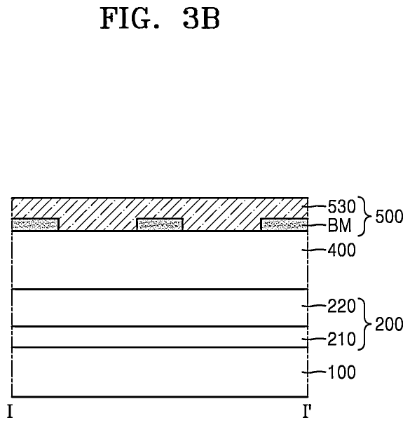

FIGS. 3A and 3B are cross-sectional views schematically illustrating a display apparatus according to one or more embodiments, taken along line I-I′ in FIG. 1.

Referring to FIGS. 3A and 3B, in the display apparatus according to an embodiment, a display layer 200 may be disposed on the substrate 100, and a thin-film encapsulation layer 400 and an optical layer 500 may be disposed on the display layer 200. In the present embodiment, a light-shielding layer BM may be arranged in the optical layer 500.

The substrate 100 may include polymer resin or glass. The substrate 100 including polymer resin may be flexible, rollable, or bendable. The display layer 200 may include a display element layer 220 including a plurality of display elements, and a pixel circuit layer 210 including pixel circuits connected to the display elements, respectively. Each of the display elements provided in the display element layer 220 may define a pixel, and the pixel circuit layer 210 may include a plurality of transistors and a plurality of storage capacitors.

The thin-film encapsulation layer 400 may be disposed on the display layer 200. The thin-film encapsulation layer 400 may prevent the display elements from being damaged by external foreign substances, such as moisture. The thin-film encapsulation layer 400 may include at least one inorganic thin-film encapsulation layer and at least one organic thin-film encapsulation layer.

The optical layer 500 may be disposed on the thin-film encapsulation layer 400. The optical layer 500 may include a configuration for reducing reflectivity of light (external light) incident toward the display apparatus from the outside and improving emission efficiency of light emitted from the display elements.

Referring to FIG. 3A, the optical layer 500 may include the light-shielding layer BM and color filters CF1 and CF2. The light-shielding layer BM may include a black matrix and may block most of light in a visible ray area. The light-shielding layer BM may be arranged between emission areas of the display elements. Alternatively, the light-shielding layer BM may be provided to include openings corresponding to the emission areas of the display elements. Light emitted from the display elements may be emitted to the outside through the openings of the light-shielding layer BM. The color filters CF1 and CF2 may be arranged to correspond to each of the display elements. The color filters CF1 and CF2 may be arranged to correspond to an opening of the light-shielding layer BM. The color filters CF1 and CF2 may include a first color filter CF1, a second color filter CF2, and a third color filter (not shown), which are of different colors from each other. The first color filter CF1, the second color filter CF2, and the third color filter may be red, green, and blue color filters, respectively.

Referring to FIG. 3B, the optical layer 500 may include a reflection control layer 530 instead of a color filter CF1 and CF2 compared to the embodiment in FIG. 3A. In other words, the optical layer 500 may include the light-shielding layer BM and the reflection control layer 530. The reflection control layer 530 may include dye and/or pigment, and may absorb light in a certain wavelength band. In an embodiment, for example, the reflection control layer 530 may absorb a first wavelength area of 480 nanometers (nm) to 505 nm and a second wavelength area of 585 nm to 605 nm, and light transmittances in the first wavelength area and the second wavelength area may be 50% or less. In other words, the reflection control layer 530 may absorb light of a wavelength outside of a red, green, or blue emission wavelength range (e.g., cyan and yellow emission wavelength ranges) of the display elements. The reflection control layer 530 may be arranged to correspond to the openings of the light-shielding layer BM. The reflection control layer 530 may be commonly disposed on a plurality of display elements. The reflection control layer 530 may be equally disposed on a plurality of display elements.

A cover window may be disposed on the optical layer 500. The cover window may be attached onto the optical layer 500 by a clear adhesive member, such as an optical clear adhesive film.

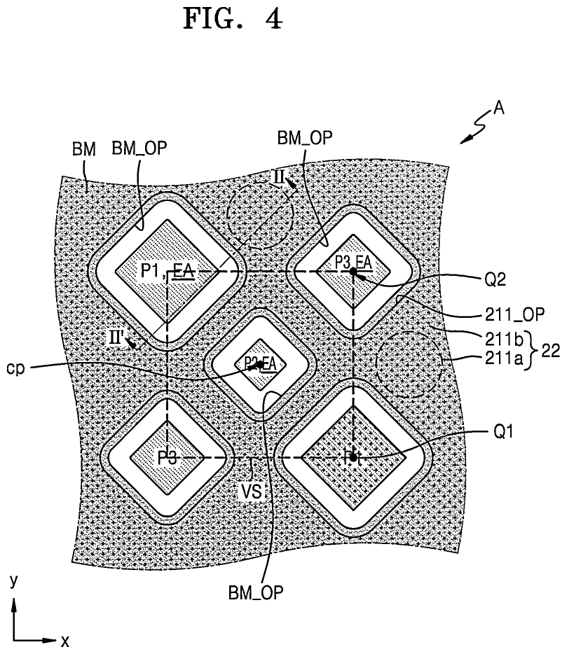

FIG. 4 is an enlarged plan view of some components of an embodiment, which may be included in region A in FIG. 1, and schematically illustrates an arrangement relationship of an opening BM_OP of the light-shielding layer BM and a first opening 211_OP of a spacer 211, which are arranged to correspond to a plurality of pixels and emission areas EA of the respective pixels.

Referring to FIG. 4, a display apparatus includes a plurality of pixels, and the plurality of pixels may include a first pixel P1, a second pixel P2, and a third pixel P3, which emit light of different colors from each other. In an embodiment, for example, the first pixel P1 may emit blue light, the second pixel P2 may emit green light, and the third pixel P3 may emit red light. However, one or more embodiments are not limited thereto. In another embodiment, for example, the first pixel P1 may emit red light, the second pixel P2 may emit green light, and the third pixel P3 may emit blue light, and various modifications may be made.

Each of the first pixel P1, the second pixel P2, and the third pixel P3 may have a quadrangular shape from among polygonal shapes. Herein, a polygon or a quadrangle includes a shape with round vertices. In other words, each of the first pixel P1, the second pixel P2, and the third pixel P3 may each have a quadrangular shape with round vertices. In another embodiment, each of the first pixel P1, the second pixel P2, and the third pixel P3 may have a circular or elliptical shape.

The first pixel P1, the second pixel P2, and the third pixel P3 may be provided in different sizes from each other. In an embodiment, for example, an area of the second pixel P2 may be less than an area of the first pixel P1 and an area of the third pixel P3, and the area of the first pixel P1 may be greater than the area of the third pixel P3. However, one or more embodiments are not limited thereto. The first pixel P1, the second pixel P2, and the third pixel P3 may be provided in substantially the same size, and various modifications may be made.

The first pixel P1, the second pixel P2, and the third pixel P3 may be arranged in a pixel array having a PenTile™ structure. In other words, in the first pixel P1, the second pixel P2, and the third pixel P3, the first pixel P1 may be positioned at a first vertex Q1 of an imaginary quadrangle VS having a center point CP of the second pixel P2 as a center point thereof, and the third pixel P3 may be positioned at a second vertex Q2 of the imaginary quadrangle VS. The quadrangle VS may be a square.

The first pixel P1 may be apart from the second pixel P2, and a center point of the first pixel P1 may be positioned at the first vertex Q1 of the imaginary quadrangle VS. The first pixel P1 may be provided in plurality, and a plurality of first pixels P1 may be apart from each other with the second pixel P2 therebetween.

The third pixel P3 may be apart from the first pixel P1 and the second pixel P2, and a center point of the third pixel P3 may be positioned at the second vertex Q2 adjacent to the first vertex Q1 of the virtual quadrangle VS. The third pixel P3 may be provided in plurality, and a plurality of third pixels P3 may be apart from each other with the first pixel P1 therebetween.

Each of the plurality of first pixels P1 and the plurality of third pixels P3 may be alternately arranged in an x direction and a y direction crossing the x direction. The first pixel P1 may be surrounded by a plurality of second pixels P2 and a plurality of third pixels P3.

In FIG. 4, an arrangement of the first pixel P1, the second pixel P2, and the third pixel P3 has a PenTile™ structure. However, one or more embodiments are not limited thereto. In another embodiment, for example, the first pixel P1, the second pixel P2, and the third pixel P3 may also be arranged in a stripe structure. In other words, the first pixel P1, the second pixel P2, and the third pixel P3 may be sequentially arranged in the x direction. In another embodiment, the first pixel P1, the second pixel P2, and the third P3 may be arranged in various pixel array structures, such as a mosaic structure, a delta structure, and the like.

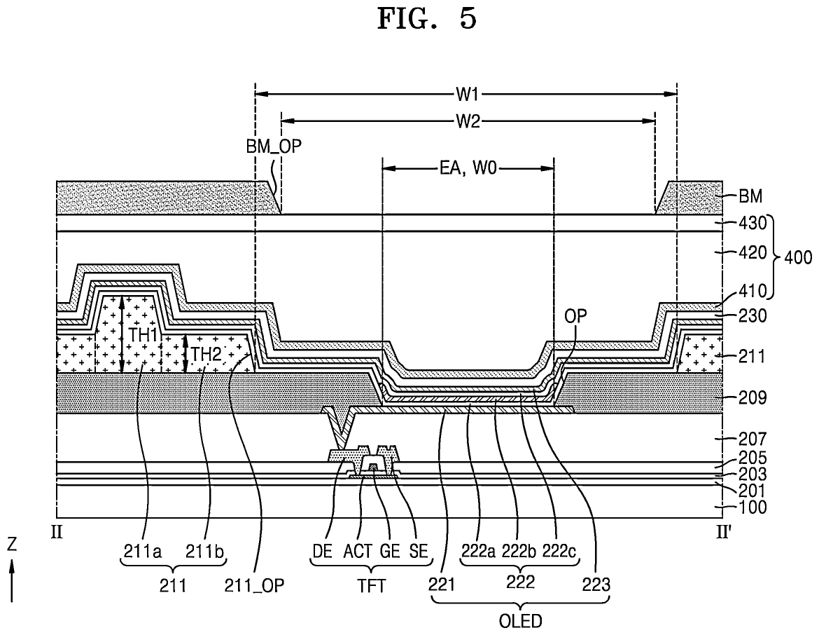

Herein, sizes of the first pixel P1, the second pixel P2, and the third pixel P3 may refer to sizes of the emission area EA of a display element implementing each of the pixels, and the emission area EA may be defined by an opening OP of a pixel-defining layer 209 (see FIG. 5).

The spacer 211 may be disposed on the pixel-defining layer 209 (see FIG. 5). The spacer 211 may define a first opening 211_OP corresponding to each of the pixels. The first opening 211_OP may be an area obtained by removing a portion of the spacer 211. An edge of the spacer that defines the first opening 211_OP may surround each of the pixels in a plan view (when viewed from a z direction).

The spacer 211 may include a first portion 211a and a second portion 211b. The first portion 211a may be arranged between each of the pixels, and may be a portion having a shape. The first portion 211a may have various shapes, such as a circle, a polygon, and the like. The first portion 211a may be repeatedly arranged at regular intervals. The second portion 211b may be a remaining portion of the spacer 211a other than the first portion 211a. The second portion 211b may be a portion extending from the first portion 211a. The first portion 211a and the second portion 211b may be integrally formed as a single body. The second portion 211b may define the first opening 211_OP.

The first portion 211a of the spacer 211 may prevent layers between the substrate 100 and the spacer 211 from being damaged by a mask used in a process of forming an emission layer 222b (see FIG. 5). The second portion 211b of the spacer 211 may supplement adhesive force between the pixel-defining layer 209 (see FIG. 5) and layers disposed on the pixel-defining layer 209. The first portion 211a and the second portion 211b of the spacer 211 may cover 70% to about 90% of an upper surface of the pixel-defining layer 209. The first portion 211a and the second portion 211b are described in detail with reference to FIG. 5.

The light-shielding layer BM disposed on the display element layer may define a second opening BM_OP corresponding each of the pixels. The second opening BM_OP may be an area obtained by removing a portion of the light-shielding layer BM, and light emitted from a display element may be emitted to the outside through the second opening BM_OP. A body of the light-shielding layer BM may include a material that absorbs external light, so that visibility of the display apparatus may be improved.

In a plan view, the second opening BM_OP of the light-shielding layer BM may have a shape surrounding each of the first, second, and third pixels P1, P2, and P3. In an embodiment, the second opening BM_OP of the light-shielding layer BM may have a quadrangular shape with round edges. An area of the second opening BM_OP of each of the light-shielding layers BM corresponding to the first, second, and third pixels P1, P2, and P3, respectively, may be greater than an area of each of the first, second, and third pixels P1, P2, and P3. However, one or more embodiments are not limited thereto. The area of the second opening BM_OP of each of the light-shielding layers BM may be provided substantially equal to the area of each of the first, second, and third pixels P1, P2, and P3 in another embodiment.

Referring to FIG. 4, a size of the second opening BM_OP of the light-shielding layer BM may be a size of the first opening 211_OP of the spacer 211 or smaller. In other words, the size of the first opening 211_OP may be equal to or greater than the size of the second opening BM_OP. When viewed in a direction perpendicular to the substrate 100 (e.g., the z direction, in a plan view), the second opening BM_OP may overlap the first opening 211_OP. An edge of the spacer 211 that defines the first opening 211_OP may surround an edge of the light-shielding layer BM that defines the second opening BM_OP. Accordingly, when viewed from a direction perpendicular to the substrate 100 (e.g., the z direction), the spacer 211 may be shielded by the light-shielding layer BM. The second portion 211b of the spacer 211 may be shielded by the light-shielding layer BM and may not be exposed.

A display apparatus according to an embodiment is described in detail below, according to a stack order shown in FIG. 5.

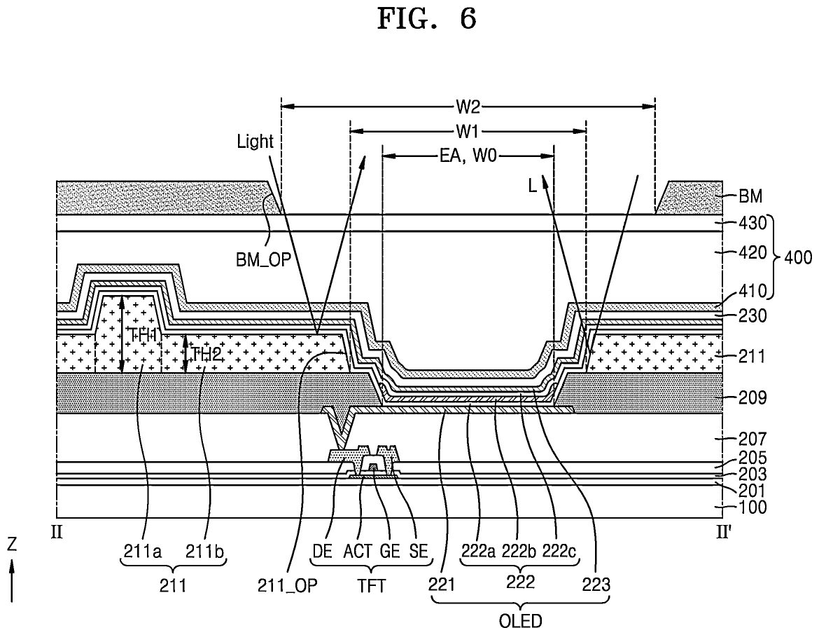

FIG. 5 is a schematic cross-sectional view of a display apparatus according to an embodiment, taken along line II-II′ in FIG. 4. FIG. 6 is a schematic cross-sectional view of a display apparatus according to a Comparative Example.

Referring to FIG. 5, the display apparatus according to an embodiment may include an organic light-emitting diode OLED, which is a display element having an emission area EA on a substrate 100, a pixel-defining layer 209 defining the emission area EA of the display element, a spacer 211 disposed on the pixel-defining layer 209, a thin-film encapsulation layer 400 covering the display element, and a light-shielding layer BM disposed on the thin-film encapsulation layer 400. In an embodiment, the display apparatus may further include a capping layer 230 between the organic light-emitting diode OLED and the thin-film encapsulation layer 400.

The substrate 100 may be a single glass layer. Alternatively, the substrate 100 may include polymer resin. The substrate 100 including polymer resin may have a stack structure of a layer, which includes the polymer resin, and an inorganic layer. In an embodiment, the substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, or/and cellulose acetate propionate, and may be flexible. The substrate 100 may include glass having silicon oxide (SiO₂) as a main component, or resin such as reinforced plastic, and may be rigid.

A thin-film transistor TFT may include a semiconductor layer Act, which includes amorphous silicon, polycrystalline silicon, or an organic semiconductor material, a gate electrode GE, a source electrode SE, and a drain electrode DE. To ensure insulation between the semiconductor layer Act and the gate electrode GE, a gate insulating layer 203 including silicon oxide, silicon nitride, and/or silicon oxynitride may be located between the semiconductor layer Act and the gate electrode GE. In addition, on the gate electrode GE, an interlayer-insulating layer 205 including an inorganic material such as silicon oxide, silicon nitride, and/or silicon oxynitride may be disposed, and the source electrode SE and the drain electrode DE may be disposed on the interlayer-insulating layer 205 described above. An insulating layer including an inorganic material may be formed through chemical vapor deposition (“CVD”) or atomic layer deposition (“ALD”).

The gate electrode GE, the source electrode SE, and the drain electrode DE may include various conductive materials. The gate electrode GE may include at least one of molybdenum, aluminum, copper, and titanium, and may have a multi-layer structure. In an embodiment, for example, the gate electrode GE may be a single molybdenum layer or may have a three-layer structure including a molybdenum layer, an aluminum layer, and another molybdenum layer. The source electrode SE and the drain electrode DE may include at least one of copper, titanium, and aluminum, and may have a multi-layer structure. In an embodiment, for example, the source electrode SE and the drain electrode DE may have a three-layer structure including a titanium layer, an aluminum layer, and another titanium layer.

Between the thin-film transistor TFT, which has such a structure, and the substrate 100, a buffer layer 201 including an inorganic material such as silicon oxide, silicon nitride, and/or silicon oxynitride may be located. This buffer layer 201 may increase flatness of an upper surface of the substrate 100 or prevent or minimize permeation of impurities from the substrate 100, etc. into the semiconductor layer Act of the thin-film transistor TFT.

A planarization insulating layer 207 may be disposed on the thin-film transistor TFT. In an embodiment, for example, the planarization insulating layer 207 may include an organic material, such as benzocyclobutene (“BCB”) or hexamethyldisiloxane (“HMDSO”). In FIG. 5, the planarization insulating layer 140 is a single layer. However, the planarization insulating layer 140 may include a plurality of layers.

The organic light-emitting diode OLED may be disposed on the planarization insulating layer 207 and connected to the thin-film transistor TFT through a contact hole. The organic light-emitting diode OLED may include a pixel electrode 221, an intermediate layer, which includes an emission layer 222b, and an opposite electrode 223.

The pixel electrode 221 may be disposed on the planarization insulating layer 207. The pixel electrode 221 may be arranged for each pixel. The pixel electrodes 221 corresponding to adjacent pixels, respectively, may be arranged apart from each other.

The pixel electrode 221 may be a reflective electrode. In some embodiments, the pixel electrode 221 may include a reflective film, which includes silver (Ag), magnesium (Mg), aluminum (AI), platinum (Pt), palladium (Pd), gold (Au), nickel (Ni), neodymium (Nd), iridium (Ir), chrome (Cr), and a compound thereof, and a transparent or semi-transparent electrode layer. The transparent or semi-transparent electrode layer may include at least one selected from the group consisting of indium tin oxide (“ITO”), indium zinc oxide (“IZO”), zinc oxide (ZnO), indium oxide (IN₂O₃), indium gallium oxide (“IGO”), and aluminum zinc oxide (“AZO”). In some embodiments, the pixel electrode 221 may have a three-layer structure of an ITO layer, an Ag layer, and another ITO layer.

The pixel-defining layer 209 may be disposed on the pixel electrode 221. The pixel-defining layer 209 may define an opening OP that exposes a central portion of the pixel electrode 221. The pixel-defining layer 209 may cover an edge of the pixel electrode 221 and increase a distance between the edge of the pixel electrode 221 and the opposite electrode 223, so as to prevent an arc, etc. from occurring at the edge of the pixel electrode 221. The pixel-defining layer 209 may include an organic insulating material such as polyamide, acrylic resin, BCB, HMDSO, and phenolic resin, and may be formed by a method such as spin coating and the like. Alternatively, the pixel-defining layer 209 may include an inorganic insulating material. Alternatively, the pixel-defining layer 209 may have a multi-layer structure including an inorganic insulating material and an organic insulating material.

In an embodiment, the pixel-defining layer 209 may include a light-blocking material and may be provided in black. The light-blocking material may include carbon black, carbon nanotubes, resin or paste including black dye, metal particles, for example, nickel, aluminum, molybdenum, and an alloy thereof metal oxide particles (e.g., chrome oxide), or metal nitride (e.g., chrome nitride). When the pixel-defining layer 209 includes a light-blocking material, reflection of external light due to metal structures disposed under the pixel-defining layer 209 may be effectively reduced.

The emission layer 222b may be arranged in the opening OP of the pixel-defining layer 209. The emission layer 222b may be an organic layer including a fluorescent or phosphorescent material emitting red, green, or blue light. This organic material may be a low-molecular weight organic material or a polymer organic material.

A first common layer 222a and a second common layer 222c may be disposed under and over the emission layer 222b, respectively. In an embodiment, for example, the first common layer 222a may include a hole transport layer (“HTL”) or may include an HTL and a hole injection layer (“HIL”). The second common layer 222c may be an element disposed over the emission layer 222b, and may include an electron transport layer (“ETL”) and/or an electron injection layer (“EIL”). The second common layer 222c may be optional. In some embodiments, the second common layer 222c may not be provided.

While the emission layer 222b is arranged for each pixel, to correspond to the opening OP of the pixel-defining layer 209, the first common layer 222a and the second common layer 222c may be common layers that are integrally formed as a single body to cover the entirety of the substrate 100, for example, a display area of the substrate 100, similar to an opposite electrode 223 to be described below.

The opposite electrode 330 may be a cathode, which is an electron injection electrode, and in this case, a metal having a low work function, an alloy, an electrically conductive compound, or any combinations thereof may be used as a material for the opposite electrode 330. The opposite electrode 330 may be a transmissive electrode, a semi-transmissive electrode, or a reflective electrode.

The opposite electrode 330 may include lithium (Li), Ag, Mg, Al, aluminum-lithium (Al—Li), calcium (Ca), magnesium-indium (Mg—In), magnesium-silver (Mg—Ag), ytterbium (Yb), Ag—Yb, ITO, IZO, or any combinations thereof. The opposite electrode 330 may have a single-layer structure including one layer, or a multi-layer structure including a plurality of layers.

The capping layer 230 may improve external emission efficiency of an organic light-emitting element by the principle of constructive interference. The capping layer 230 may include a material having a refractive index (at 589 nm) of 1.6 or more. A thickness of the capping layer 230 may be 1 nm to 200 nm, for example, 5 nm to 150 nm, or 10 nm to 100 nm.

The capping layer 230 may be an organic capping layer including an organic material, an inorganic capping layer including an inorganic material, or a composite capping layer including an organic material and an inorganic material.

In an embodiment, for example, the capping layer 230 may include carbocyclic compounds, heterocyclic compounds, amine group-containing compounds, porphine derivatives, phthalocyanine derivatives, naphthalocyanine derivatives, alkali metal complexes, alkaline earth metal complexes, or any combinations thereof. The carbocyclic compounds, the heterocyclic compounds, and the amine group-containing compounds may be optionally substituted with a substituent including oxygen (O), nitrogen (N), sulfur(S), selenium (Se), silicon (Si), fluorine (F), chlorine (CI), bromine (Br), iodine (I), or any combinations thereof.

The thin-film encapsulation layer 400 may be disposed on the capping layer 230 and may seal a plurality of organic light-emitting diodes OLED. The thin-film encapsulation layer 400 may include at least one inorganic encapsulation layer and at least one organic encapsulation layer. In an embodiment, for example, the thin-film encapsulation layer 400 may include a first inorganic encapsulation layer 410, a first organic encapsulation layer 420, and a second inorganic encapsulation layer 430, as shown in FIG. 5.

The first inorganic encapsulation layer 410 and the second inorganic encapsulation layer 430 may include one or more inorganic insulating materials selected from among aluminum oxide, titanium oxide, tantalum oxide, hafnium oxide, zinc oxide, silicon oxide, silicon nitride, silicon oxynitride, and silicon oxycarbide (SiOCₓ, where x>0).

The first organic encapsulation layer 420 may relieve internal stress of the first inorganic encapsulation layer 410 and/or the second inorganic encapsulation layer 430. The first organic encapsulation layer 420 may include a polymer-based material. A polymer-based material may include polyethylene terephthalate, polyethylene naphthalate, polycarbonate, polyimide, polyethylene sulfonate, polyoxymethylene, polyarylate, HMDSO, acryl-based resin (e.g., poly(methyl methacrylate), polyacrylic acid, etc.), or any combinations thereof.

The first organic encapsulation layer 420 may be formed by applying a monomer having flowability and curing a monomer layer by using heat or light such as ultraviolet rays. Alternatively, the first organic encapsulation layer 420 may be formed by applying the polymer-based material and then carrying out patterning. In an embodiment, for example, the first organic encapsulation layer 420 may include a low-dielectric constant acryl-based material, and may be formed through a photomask process.

Even when cracks occur within the thin-film encapsulation layer 400 through the multi-layer structure described above, the thin-film encapsulation layer 400 may not allow those cracks to be connected between the first inorganic encapsulation layer 410 and the first organic encapsulation layer 420 or between the first organic encapsulation layer 420 and the second inorganic encapsulation layer 430. Through this, the formation of a passage through which moisture, oxygen, or the like from the outside permeates into the display area DA may be prevented or minimized.

In some embodiments, the first inorganic encapsulation layer 410 may include a material and/or structure different from a material and/or structure of the second inorganic encapsulation layer 430. The first inorganic encapsulation layer 410 may be provided by stacking a plurality of sub-layers. The plurality of sub-layers may be layers that may be distinguished from each other, and may each have a thickness smaller than a thickness of the second inorganic encapsulation layer 430. In an embodiment, for example, a thickness of each of the sub-layers may be 0.01 to 0.1 times the thickness of the second inorganic encapsulation layer 430. In some embodiments, the thickness of each of the sub-layers may be 100 angstroms (Å) to 100 Å, and the thickness of the second inorganic encapsulation layer 430 may be several micrometers (μm).

In some embodiments, the first inorganic encapsulation layer 410 may be provided by alternately stacking a first sub-layer, which includes silicon nitride (SiNₓ), and a second sub-layer including SiOCₓ. The first sub-layer and the second sub-layer may be formed in a dense structure through a plasma chemical vapor deposition (“PECVD”), ALD, etc. Accordingly, a sealing property may be excellent even when the thickness is formed small.

Referring to FIG. 5, the spacer 211 may be disposed on the pixel-defining layer 209. The spacer 211 may be arranged between the pixel-defining layer 209 and the opposite electrode 223. The spacer 211 may include an organic insulating material such as polyimide, polyamide, acrylic resin, BCB, HMDSO, phenolic resin, and the like. Alternatively, the spacer 211 may include an insulating material. Alternatively, the spacer 211 may have a multi-layer structure including an insulating material and an organic insulating material.

The spacer 211 according to an embodiment may include a first portion 211a for supporting a mask, and a second portion 211b for enhancing bonding strength. The first portion 211a may have a portion having a shape and may be repeatedly arranged between pixels, and the second portion 211b may be the remaining portions other than the first portion 211a.

A thickness TH1 of the first portion 211a may be greater than a thickness TH2 of the second portion 211b. In other words, the first portion 211a may be a portion of the spacer 211 that protrudes in a z direction. In an embodiment, the thickness TH1 of the first portion 211a may be at least twice the thickness TH2 of the second portion 211b. The first portion 211a and the second portion 211b may be simultaneously formed. The first portion 211a may be formed by using a full-tone mask, and the second portion 211b may be formed by using a half-tone mask.

The thickness TH1 of the first portion 211a may be 8,000 Å to 15,000 Å. The thickness TH1 of the first portion 211a may be about 12,000 Å. When the thickness TH1 of the first portion 211a is 8,000 Å to 15,000 Å, the first portion 211a may prevent a thickness of the display apparatus from increasing while preventing other layers from being damaged by a mask used to form the emission layer 222b.

The thickness TH2 of the second portion 211b may be 2,000 Å to 6,000 Å. The thickness TH2 of the second portion 211b may be about 4,000 Å. In an embodiment, when the pixel-defining layer 209 includes a light-blocking material, due to the nature of the material, bonding strength between the pixel-defining layer 209 and the opposite electrode 223 may be weakened. Thus, a strength of the display apparatus may be weakened. When the second portion 211b is disposed on the pixel-defining layer 209 with a thickness smaller than a thickness of the first portion 211a, adhesive force of layers disposed over the pixel-defining layer 209 may be supplemented, and thus, the strength of the display apparatus may be enhanced.

The spacer 211 may define a first opening 211_OP that overlaps the emission area EA of the organic light-emitting diode OLED in a plan view. The emission area EA may be defined by the opening OP of the pixel-defining layer 209. A body portion of the spacer 211 including the first portion 211a and the second portion 211b may overlap a body portion of the pixel-defining layer 209 in a plan view. Here, the body portion of the spacer 211 may be a portion distinguished from the first opening 211_OP of the spacer 211 and may refer to a portion having a volume.

The light-shielding layer BM may be disposed on the thin-film encapsulation layer 400. The light-shielding layer BM may reduce reflectivity of light (external light) incident toward the display apparatus 10 from the outside and improve contrast of light emitted from the display elements.

The light-shielding layer BM may have a wavelength spectrum that generally absorbs wavelengths in a visible ray band, about 380 nm to about 780 nm. The light-shielding layer BM may be provided in black. In an embodiment, for example, the light-shielding layer BM may be provided to include a light-blocking material in an organic material. In an embodiment, for example, the light-blocking material may include metal particles, e.g., nickel, Al, molybdenum, and an alloy thereof; metal oxide particles (e.g., chrome oxide), or metal nitride particles (e.g., chrome nitride), carbon black, carbon nanotubes, resin or paste including black dye, etc.

The light-shielding layer BM may include the second opening BM_OP. The second opening BM_OP may overlap the emission area EA of the organic light-emitting diode OLED in a plan view. A body portion of the light-shielding layer BM may overlap the body portion of the pixel-defining layer 209 in a plan view. The body portion of the light-shielding layer BM may overlap the body portion of the spacer 211 in a plan view. Here, the body portion of the light-shielding layer BM may be a portion distinguished from the second opening BM_OP of the light-shielding layer BM and may refer to a portion having a volume. A color filter or a reflection control layer may be provided within the second opening BM_OP, as described with reference to FIGS. 3A and 3B.

Because the light-shielding layer BM is disposed over the thin-film encapsulation layer 400, that is, because the light-shielding layer BM is disposed far away from the organic light-emitting diode OLED, which is a display element, a size of the second opening BM_OP may be determined in consideration of a side viewing angle of the display apparatus. In this case, reflected light due to members exposed by the second opening BM_OP of the light-shielding layer BM may be generated.

In an embodiment, for example, a width W2 of the second opening BM_OP of the light-shielding layer BM may be provided greater than a width W0 of the opening OP of the pixel-defining layer 209 (W0<W2). In an embodiment, an edge of the second opening BM_OP may be apart outward by about 2 μm to about 6 μm compared to an edge of the opening OP of the pixel-defining layer 209.

A first width W1 of the first opening 211_OP of the spacer 211 may be greater than or equal to the second width of the second opening BM_OP of the light-shielding layer BM (W2≤W1). In a plan view, an edge of the spacer 211 that defines the first opening 211_OP may be in a shape of surrounding an edge of the light-shielding layer BM that defines the second opening BM_OP. In a plan view, the body portion of the spacer 211 may be shielded by the body portion of the light-shielding layer BM. In a plan view, at least a portion of the body portion of the light-shielding layer BM may be arranged inside the first opening 211_OP.

Referring to the Comparative Example shown in FIG. 6, a first width W1 of a first opening of a spacer 211 is smaller than a second width W2 of a second opening of a light-shielding layer BM. A size of the first opening of the spacer is smaller than a size of an opening of the light-shielding layer. Accordingly, a portion of a body portion of the spacer may be exposed without being shielded by the light-shielding layer. When the body portion of the spacer is not shielded by the light-shielding layer, light L incident from the outside may be reflected by an upper surface or side surface of the spacer. In other words, when the spacer is arranged, reflected light due to the spacer may be generated.

In general, as the thickness of the spacer decreases, a reflectivity deviation due to a thickness deviation may be large. Accordingly, when external light reflection occurs on an upper surface of a second portion provided to be thinner than a first portion, stains may occur due to reflectivity deviation. In addition, when external light is incident on a side surface of a tapered spacer, a deviation of visibility may occur according to a viewing angle due to a deviation in tapering.

Referring to FIG. 5 again, according to an embodiment, unlike the Comparative Example, the second width W2 of the second opening BM_OP of the light-shielding layer BM may be at least the width W0 of the opening OP of the pixel-defining layer 209 but not more than the first width W1 of the first opening 211_OP of the spacer 211 (W0≤W2≤W1). In other words, the spacer 211 may be arranged in an area that may be shielded by the light-shielding layer BM. Accordingly, external light reflectivity and stains caused by external light reflection may be effectively reduced.

In an embodiment, for example, in an embodiment, the pixel-defining layer 209 may include a light-blocking material to reduce external light reflection caused by metal structures disposed under the pixel-defining layer 209, and the spacer 211 may include the second portion 211b to supplement bonding force of the pixel-defining layer 209. Because the second portion 211b of the spacer 211 is arranged in an area that may be shielded by the light-shielding layer BM, light incident from the outside through the second opening BM_OP of the light-shielding layer BM may reach the pixel-defining layer 209 instead of the second portion 211b of the spacer 211, so that external light reflection may be effectively reduced. Through this, in a display apparatus to which the light-shielding layer BM is applied, a strength of the display apparatus may be enhanced while reflective color may be improved.

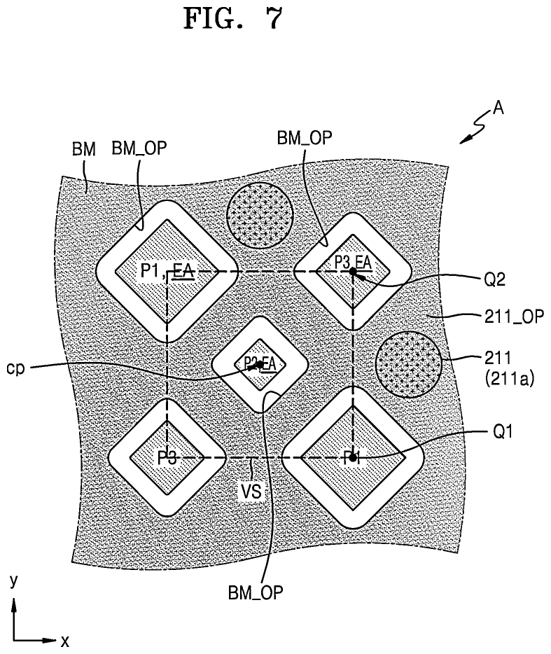

FIG. 7 is an enlarged plan view of some components of an embodiment that may be included in region A in FIG. 1. In FIG. 7, the same reference characters as those of FIG. 4 denote the same members, and redundant descriptions thereof are omitted.

A display apparatus may include a plurality of pixels, and the plurality of pixels may include a first pixel P1, a second pixel P2, and a third pixel P3, which emit light of different colors from each other. In an embodiment, for example, the first pixel P1 may emit blue light, the second pixel P2 may emit green light, and the third pixel P3 may emit red light.

The spacer 211 may define the first opening 211_OP corresponding to each of the pixels. The first opening 211_OP may be an area obtained by removing a portion of the spacer 211.

In this embodiment, the spacer 211 may be in a shape in which a shape is repeatedly arranged between each of the pixels. The spacer 211 may have various shapes such as a circle, a quadrangle, and the like. It may be understood that the spacer 211 includes only the first portion 211a other than the second portion 211b in FIG. 4. A thickness of the spacer 211 may be 8,000 Å to 15,000 Å. Alternatively, the thickness of the spacer 211 may be about 12,000 Å. The spacer 211 may cover 50% or less of an upper surface of the pixel-defining layer 209. That is, in this embodiment, a total sum of areas of the spacers 211 may be less than the area of the first opening 211_OP in a plan view, while in the embodiment of FIG. 4, the area of the spacer 211 may be more than a total sum of the areas of the first opening 211_OP in a plan view.

The light-shielding layer BM may include the second opening BM_OP corresponding to each of the pixels. The second pixel BM_OP may be an area obtained by removing a portion of the light-shielding layer BM, and light emitted from a display element may be emitted to the outside through the second opening BM_OP.

Like the embodiment of FIG. 4, in this embodiment of FIG. 7, a size of the first opening 211_OP of the spacer 211 may be greater than a size of the second opening BM_OP of the light-shielding layer BM. The first opening 211_OP may expose 50% or more of the upper surface of the pixel-defining layer 209. In a plan view, the spacer 211 may be shielded by the light-shielding layer BM. External light incident through the second opening BM_OP of the light-shielding layer BM may not reach the spacer 211. Accordingly, external light reflection caused by the spacer 211 may be fundamentally blocked.

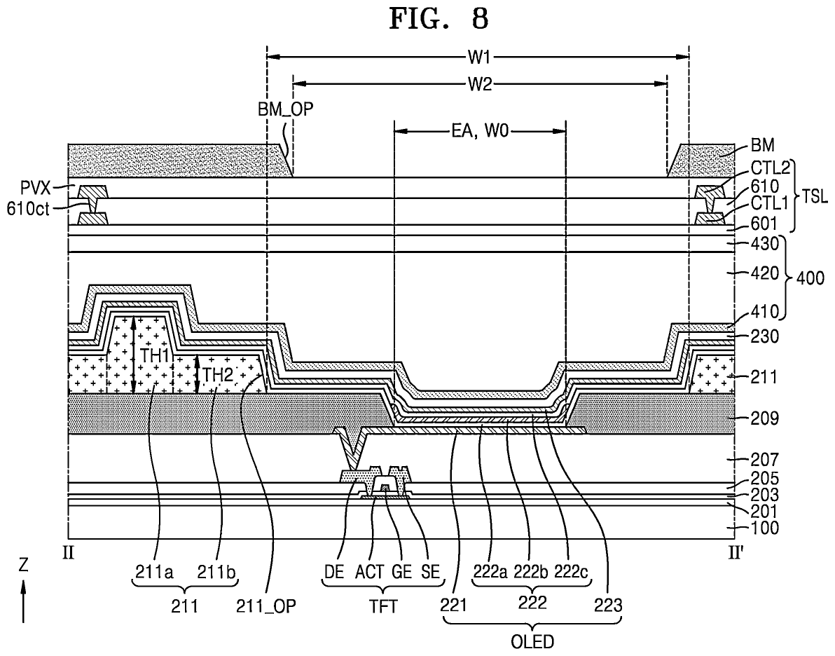

FIG. 8 is a cross-sectional view schematically illustrating a display apparatus according to an embodiment. In FIG. 8, the same reference characters as those of FIG. 5 denote the same members, and redundant descriptions thereof are omitted.

The display apparatus according to an embodiment may include an organic light-emitting diode OLED, which is a display element having an emission area EA on a substrate 100, a pixel-defining layer 209 for defining an emission area EA of the display element, a spacer 211 disposed on the pixel-defining layer 209, a thin-film encapsulation layer 400 covering the display element, and a light-shielding layer BM disposed over the thin-film encapsulation layer 400. In an embodiment, the display apparatus may further include a capping layer 230 between the organic encapsulation layer OLED and the thin-film encapsulation layer 400.

In the present embodiment, a touch sensing layer TSL may be arranged between the thin-film encapsulation layer 400 and the light-shielding layer BM. The touch sensing layer TSL may be a layer for sensing a user's touch input and may detect a user's touch input by using at least one of various touch methods, including a resistive method, a capacitive method, and the like.

The touch sensing layer TSL may be disposed on the thin-film encapsulation layer 400. The touch sensing layer TSL may include first and second sub-conductive layers CTL1 and CTL2 and a touch insulating layer 610. In addition, the touch sensing layer TSL may further include a touch buffer layer 601.

The touch buffer layer 601 may be directly formed on the thin-film encapsulation layer 400. The touch buffer layer 601 may prevent damage to the thin-film encapsulation layer 400, and the touch sensing layer TSL may block an interference signal that may occur when the display apparatus is driven. The touch buffer layer 601 may include an inorganic insulating material, such as silicon oxide (SiOₓ), silicon nitride (SiNₓ), and silicon oxynitride (SiOₓN_{y}), or an organic material, and may be a layer or layers.

Over the touch buffer layer 601, the first sub-conductive layer CTL1, the touch insulating layer 610, and the second sub-conductive layer CTL2 may be sequentially stacked. The first sub-conductive layer CTL1 and the second sub-conductive layer CTL2 may be disposed under and over the touch insulating layer 610, respectively. In some embodiments, the second sub-conductive layer CTL2 may act as a sensor unit for detecting whether a contact is made, and the first sub-conductive layer CTL1 may serve as a connection unit for connecting the second sub-conductive layer CTL2, which is patterned, in one direction. In another embodiment, the first sub-conductive layer CTL1 may act as a sensor unit for detecting whether a contact is made, and the second sub-conductive layer CTL2 may serve as a connection unit for connecting the first sub-conductive layer CTL1, which is patterned, in one direction.

In some embodiments, the first sub-conductive layer CTL1 and the second sub-conductive layer CTL2 may both act as sensor units. In this case, the first sub-conductive layer CTL1 and the second sub-conductive layer CTL2 may be connected to each other through a contact hole 610ct defined in the touch insulating layer 610. As described above, when the first sub-conductive layer CTL1 and the second sub-conductive layer CTL2 are both used as sensor units, resistance of a touch electrode may be reduced, and a response speed of the touch sensing layer TSL may be enhanced.

In some embodiments, the first sub-conductive layer CTL1 and the second sub-conductive layer CTL2 may be formed in a mesh structure, so that light emitted from the organic light-emitting diode OLED may pass therethrough. Accordingly, the first sub-conductive layer CTL1 and the second sub-conductive layer CTL2 may be arranged not to overlap an emission area of the organic light-emitting diode OLED in a plan view.

The first sub-conductive layer CTL1 and the second sub-conductive layer CTL2 may include a metal layer or a transparent conductive layer, and the metal layer may include molybdenum (Mo), Ag, titanium (Ti), copper (Cu), Al, and an alloy thereof. The transparent conductive layer may include a transparent conductive oxide, such as ITO, IZO, ZnO, and indium tin zinc oxide (“ITZO”). In addition, the transparent conductive layer may include conductive polymers, such as poly(3,4-ethylenedioxythiophene) (“PEDOT”), metal nanowires, carbon nanotubes, graphene, etc. In an embodiment, each of the first sub-conductive layer CTL1 and the second sub-conductive layer CTL2 may have a three-layer structure of a Ti layer, an Al layer, and another Ti layer.

The touch insulating layer 610 may include an inorganic material or an organic material. The inorganic material may be at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material may be at least one of acryl-based resin, methacryl-based resin, polyisoprene, vinyl-based resin, epoxy-based resin, urethane-based resin, cellulose-based resin, and perylene-based resin.

A protective layer PVX may be disposed on the touch insulating layer 610 to cover the second sub-conductive layer CTL2. The protective layer PVX may protect the touch sensing layer TSL. The protective layer PVX may include an inorganic material or an organic material. The inorganic material may be at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material may be at least one of acryl-based resin, methacryl-based resin, polyisoprene, vinyl-based resin, epoxy-based resin, urethane-based resin, cellulose-based resin, and perylene-based resin. This protective layer PVX may be omitted in some cases.

The light-shielding layer BM may be disposed on the touch sensing layer TSL and may reduce external light reflection caused by conductive layers included in the touch sensing layer, that is, the first sub-conductive layer CTL1 and the second sub-conductive layer CTL2. The light-shielding layer BM may include the second opening BM_OP corresponding to the emission area EA of the display element, and a color filter or a reflection control layer may be arranged in the second opening BM_OP.

In the present embodiment, the touch sensing layer TSL is arranged between the thin-film encapsulation layer 400 and the light-shielding layer BM. However, one or more embodiments are not limited thereto. The touch sensing layer TSL may include an additional touch film to be attached to an upper portion of the light-shielding layer BM, and various modifications may be made.

As described above, in the display apparatus according to an embodiment, a size of an opening of a spacer is controlled to enhance a strength of the display apparatus and simultaneously improve reflective color of the display apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a display element disposed on the substrate;
a pixel-defining layer disposed on the substrate and defining an opening that defines an emission area of the display element;
a spacer disposed on the pixel-defining layer and defining a first opening that overlaps the opening of the pixel-defining layer;
a thin-film encapsulation layer disposed on the display element; and
a light-shielding layer disposed on the thin-film encapsulation layer and defining a second opening corresponding to the emission area of the display element,
wherein a size of the first opening is greater than or equal to a size of the second opening in a plan view.

2. The display apparatus of claim 1, wherein the spacer comprises: a first portion having a certain shape; and a second portion that defines the first opening.

3. The display apparatus of claim 2, wherein the first portion and the second portion are integrally provided as a single body.

4. The display apparatus of claim 2, wherein a thickness of the first portion is greater than a thickness of the second portion.

5. The display apparatus of claim 2, wherein a thickness of the first portion is about 8,000 angstroms (Å) to about 15,000 Å, and a thickness of the second portion is about 2,000 Å to about 6,000 Å.

6. The display apparatus of claim 1, wherein the size of the second opening is greater than a size of the opening of the pixel-defining layer in the plan view.

7. The display apparatus of claim 1, wherein the pixel-defining layer comprises a light-blocking material.

8. The display apparatus of claim 7, wherein the spacer comprises photosensitive polyimide (PSPI).

9. The display apparatus of claim 1, further comprising a color filter in the second opening of the light-shielding layer.

10. The display apparatus of claim 1, further comprising a reflection control layer in the second opening of the light-shielding layer,
wherein the reflection control layer absorbs a first wavelength range of about 480 nanometers (nm) to about 505 nm, and a second wavelength range of about 585 nm to about 605 nm.

11. The display apparatus of claim 1, further comprising a touch sensing layer between the thin-film encapsulation layer and the light-shielding layer.

12. A display apparatus comprising:
a substrate;
a display element disposed on the substrate;
a pixel-defining layer disposed on the substrate and defining an opening that defines an emission area of the display element;
a spacer disposed on the pixel-defining layer and defining a first opening that overlaps the opening of the pixel-defining layer;
a thin-film encapsulation layer disposed on the display element; and
a light-shielding layer disposed on the thin-film encapsulation layer and defining a second opening corresponding to the emission area of the display element,
wherein, in a plan view, an edge of the spacer that defines the first opening surrounds an edge of the light-shielding layer that defines the second opening.

13. The display apparatus of claim 12, wherein the spacer comprises: a first portion having a certain shape; and a second portion extending from the first portion and defining the first opening.

14. The display apparatus of claim 13, wherein a thickness of the first portion is greater than a thickness of the second portion.

15. The display apparatus of claim 12, wherein a size of the first opening is greater than or equal to a size of the second opening.

16. The display apparatus of claim 12, wherein a size of the second opening is greater than a size of the opening of the pixel-defining layer.

17. The display apparatus of claim 12, wherein the pixel-defining layer comprises a light-blocking material.

18. The display apparatus of claim 12, further comprising a color filter in the second opening of the light-shielding layer.

19. The display apparatus of claim 12, further comprising a reflection control layer in the second opening of the light-shielding layer,
wherein the reflection control layer absorbs a first wavelength range of about 480 nm to about 505 nm, and a second wavelength range of about 585 nm to about 605 nm.

20. The display apparatus of claim 12, wherein the thin-film encapsulation layer comprises, on the spacer, a first inorganic encapsulation layer, an organic encapsulation layer, and a second inorganic encapsulation layer.
